(19) United States
(12) Patent Application Publication
(10) Pub. No.: US 2009/0159994 A1
(43) Pub. Date: Jun. 25, 2009

(54) SEMICONDUCTOR DEVICE AND METHOD OF MANUFACTURING THE SAME

(76) Inventor: Young Tack PARK, Bucheon-si (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/327,087

(22) Filed: Dec. 3, 2008

(30) Foreign Application Priority Data
Dec. 21, 2007 (KR) 10-2007-0135806

(51) Int. Cl. H01L 29/78; H01L 21/336

(52) U.S. Cl. 257/413; 438/303; 257/E29.255; 257/E21.409

(57) ABSTRACT

Semiconductor devices and manufacturing methods thereof are provided. A semiconductor device can include a gate dielectric, a gate electrode, sidewall spacers, and source and drain regions. The gate electrode can include an electrode seed layer and an electrode metal layer. In another embodiment, the gate electrode can be formed of a deposited metal silicon layer.

### CROSS-REFERENCE TO RELATED APPLICATION

The present application claims the benefit under 35 U.S.C. §119 of Korean Patent Application No. 10-2007-0135806, filed Dec. 21, 2007, which is hereby incorporated by reference in its entirety.

### BACKGROUND

A metal oxide semiconductor field effect transistor (MOSFET) is typically manufactured by forming a gate electrode and source and drain regions in an active region of a semiconductor substrate.

In the related art, in order to attempt to lower the resistance of the gate electrode in a MOS transistor, a polysilicon layer is generally formed, and then impurity ions are implanted into the polysilicon layer. Also, the thickness of the polysilicon layer is sometimes adjusted.

### BRIEF SUMMARY

Embodiments of the present invention provide a semiconductor device and manufacturing method thereof which can give a reduced-resistance gate electrode.

In one embodiment, a semiconductor device can comprise: a gate dielectric on a semiconductor substrate; and a gate electrode on the gate dielectric, wherein the gate electrode comprises an electrode seed layer on the gate dielectric and an electrode metal layer on the electrode seed layer.

In another embodiment, a method of manufacturing a semiconductor device can comprise: forming a gate dielectric on a semiconductor substrate; and forming a gate electrode on the gate dielectric, wherein the gate electrode comprises an electrode seed layer on the gate dielectric and an electrode metal layer on the electrode seed layer.

In yet another embodiment, a semiconductor device can comprise: a gate dielectric on a semiconductor substrate; and a gate electrode on the gate dielectric, wherein the gate electrode comprises an electrode metal silicon layer deposited on the gate dielectric.

In still another embodiment, a method of manufacturing a semiconductor device can comprise: forming a gate dielectric on a semiconductor substrate; and forming a gate electrode on the gate dielectric, wherein the gate electrode comprises an electrode metal silicon layer deposited on the gate dielectric.

The details of one or more embodiments are set forth in the accompanying drawings and the detailed description below. Other features will be apparent to a skilled artisan from the description, the drawings, and the claims.

### BRIEF DESCRIPTION OF THE DRAWINGS

FIG. 1 is a cross-sectional view of a semiconductor device according to an embodiment of the present invention.

FIGS. 2 to 4 are cross-sectional views showing a method of manufacturing a semiconductor device according to an embodiment of the present invention.

FIG. 5 is a cross-sectional view of a semiconductor device according to another embodiment of the present invention.

FIGS. 6 to 8 are cross-sectional views showing a method of manufacturing a semiconductor device according to another embodiment of the present invention.

### DETAILED DESCRIPTION

Hereinafter, a semiconductor device and a method of manufacturing the same will now be described with reference to the accompanying drawings.

When the terms “on” or “over” or “above” are used herein, when referring to layers, regions, patterns, or structures, it is understood that the layer, region, pattern, or structure can be directly on another layer or structure, or intervening layers, regions, patterns, or structures may also be present. When the terms “under” or “below” are used herein, when referring to layers, regions, patterns, or structures, it is understood that the layer, region, pattern, or structure can be directly under the other layer or structure, or intervening layers, regions, patterns, or structures may also be present.

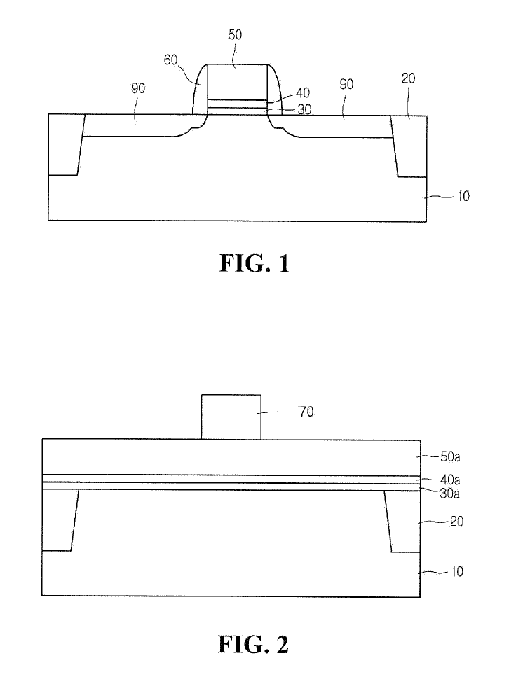

Referring to FIG. 1, a device isolation layer 20 defining an active region can be provided in a semiconductor substrate 10. A gate electrode can be disposed in the active region and can include an electrode seed layer 40 and an electrode metal layer 50 on a gate dielectric 30.

Sidewall spacers 60 can be disposed on sides of the gate electrode, and source and drain regions 90 can be provided in the semiconductor substrate 10 at sides of the gate electrode.

The device isolation layer 20 can include any suitable material known in the art. In an embodiment, the device isolation layer 20 can include an oxide layer. The device isolation layer 20 can be formed through any suitable process known in the art, for example, a shallow trench isolation (STI) process or a local oxidation of silicon (LOCOS) process.

The gate dielectric 30 can include any suitable material(s) known in the art. For example, the gate dielectric 30 can include an oxide layer, a nitride layer, or a multilayered structure with an oxide layer and a nitride layer stack.

The electrode seed layer 40 can help allow the electrode metal layer 50 to be deposited more easily. The electrode seed layer 40 can be obtained by any suitable process known in the art. In an embodiment, the electrode seed layer 40 can be obtained by thermally decomposing SiH₄ to form a thin polysilicon layer on the gate dielectric 30 using a low pressure chemical vapor deposition (LPCVD) method. The electrode seed layer 40 can have a thickness of from about 10 Å to about 200 Å.

The electrode metal layer 50 can be obtained by any suitable process known in the art. In an embodiment, the electrode metal layer 50 can be obtained by decomposing a gas containing tungsten (W), titanium (Ti), cobalt (Co), or any combination thereof using heat or plasma, and depositing it on the electrode seed layer 40 in a deposition chamber. Accordingly, the electrode metal layer 50 can include W, Ti, Co, or any combination thereof.

Thus, the gate electrode can comprise the electrode seed layer 40 and the electrode metal layer 50 on the gate dielectric 30 and can provide the advantage of a lower resistance than that of a gate electrode formed of polysilicon according to the related art.

Additionally, according to embodiments of the present invention, the low resistance of the gate electrode can allow the gate electrode to have a small thickness, thereby allowing a step height between the semiconductor substrate 10 and the gate electrode to be reduced. This can allow an interlayer dielectric that may be subsequently formed on the semiconductor substrate 10 to be thin. Accordingly, a contact connected to the source and drain regions 90 can be formed more easily.

A method of manufacturing a semiconductor device according to an embodiment will now be described.

Referring to FIG. 2, a device isolation layer 20 defining an active region can be formed in a semiconductor substrate 10. A gate dielectric layer 30a, a seed layer 40a, and a metal layer 50a can be formed on the semiconductor substrate 10. A photoresist pattern 70 can be formed on the metal layer 50a.

The device isolation layer 20 can be formed of any suitable material known in the art. In an embodiment, the device isolation layer 20 can be formed of an oxide. The device isolation layer 20 can be formed through any suitable process known in the art, for example, an STI process or a LOCOS process.

The gate dielectric layer 30a can be formed of any suitable material(s) known in the art. For example, the gate dielectric layer 30a can be formed of an oxide layer, a nitride layer, or a multilayered structure with an oxide layer and a nitride layer stack.

The seed layer 40a can help allow the metal layer 50 to be deposited more easily. The seed layer 40a can be formed through any suitable process known in the art. In an embodiment, the seed layer 40a can be formed by thermally decomposing SiH₄ at a temperature of from about 500° C. to about 700° C. to form a thin polysilicon layer on the gate dielectric layer 30a, using an LPCVD method. The seed layer 40a can be formed to a thickness of from about 10 Å and about 200 Å.

The metal layer 50a can be formed by any suitable process known in the art. In an embodiment, the metal layer 50a can be formed by decomposing a gas containing W, Ti, Co, or any combination thereof using heat or plasma, and depositing it on the seed layer 40a in a deposition chamber. After depositing the metal layer 50a, a heat treatment process can be performed to stably bond the metal layer 50a and the seed layer 40a to each other.

Accordingly, the metal layer 50a can include W, Ti, Co, or any combination thereof. In an embodiment, a WSi layer, a TiSi layer, or a CoSi layer can be formed at a boundary between the metal layer 50a and the seed layer 40a.

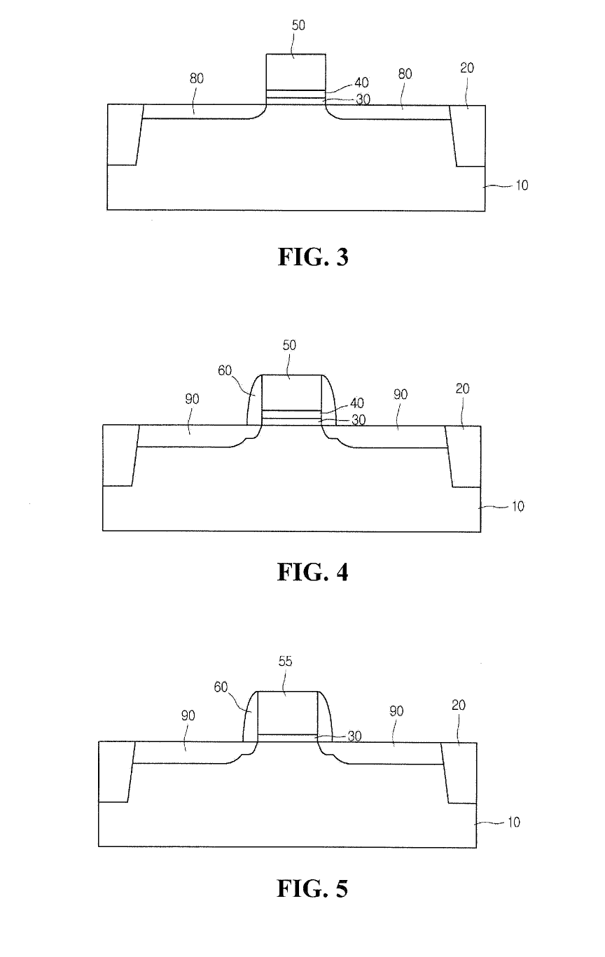

Referring to FIG. 3, portions of the metal layer 50a, the seed layer 40a, and the gate dielectric layer 30a can be selectively removed using the photoresist pattern 70 as a mask to form a gate electrode including an electrode metal layer 50 and an electrode seed layer 40 on a gate dielectric 30.

Thereafter, an implantation process of impurity ions can be performed, using the gate electrode as a mask, to form lightly doped drain (LDD) regions 80.

Referring to FIG. 4, sidewall spacers 60 can be formed on sides of the gate electrode, and impurity ions can be implanted using the sidewall spacers 60 and the gate electrode as a mask, resulting in the formation of source and drain regions 90.

The sidewall spacers 60, the LDD regions 80, and source and drain regions 90 can each be formed through any suitable process known in the art.

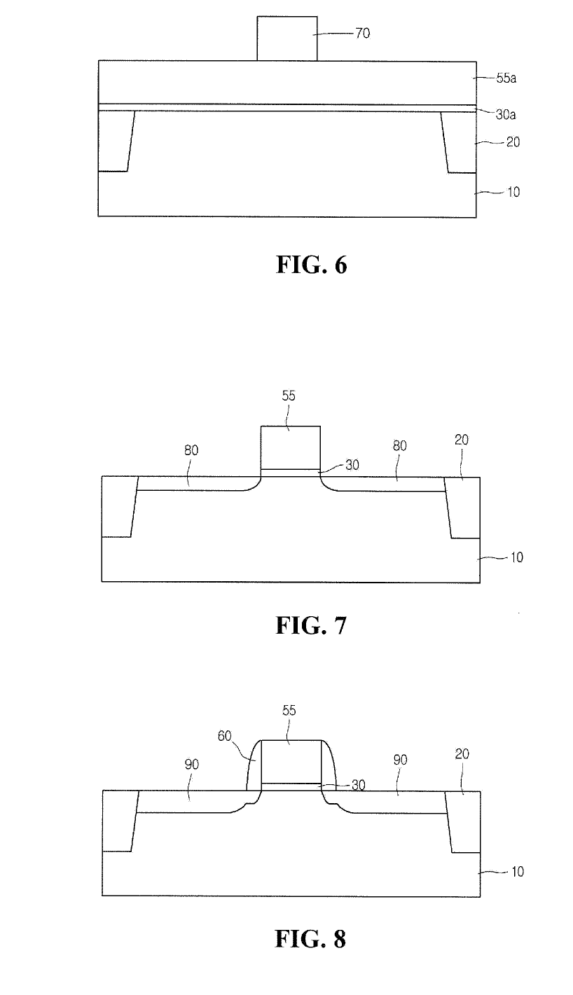

FIG. 5 is a cross-sectional view of a semiconductor device according to another embodiment of the present invention, and FIGS. 6 to 8 are cross-sectional views showing a method of manufacturing the semiconductor device shown in FIG. 5.

Referring to FIG. 5, a device isolation layer 20 defining an active region can be provided in a semiconductor substrate 10. A gate electrode can be disposed in the active region and can include an electrode metal silicon layer 55 on a gate dielectric 30.

The device isolation layer 20 can include any suitable material known in the art. In an embodiment, the device isolation layer 20 can include an oxide layer. The device isolation layer 20 can be formed through any suitable process known in the art, for example, an STI process or a LOCOS process.

The gate dielectric 30 can include any suitable material(s) known in the art. For example, the gate dielectric 30 can include an oxide layer, a nitride layer, or a multilayered structure with an oxide layer and a nitride layer stack.

In an embodiment, the electrode metal silicon layer 55 can be obtained in such a way that a Si-containing gas and a gas containing W, Ti, Co, or any combination thereof are decomposed using heat or plasma, and deposited on the gate dielectric 30 in a deposition chamber. For example, the Si-containing gas can be SiH₄.

The electrode metal silicon layer 55 can be, for example, a WSi layer, a TiSi layer or a CoSi layer.

Sidewall spacers can be disposed on sides of the gate electrode, and source and drain regions 90 can be provided in the semiconductor substrate 10 at sides of the gate electrode.

The gate electrode containing the electrode metal silicon layer 55, as described above, can provide the advantage of giving a resistance of the gate electrode lower than that of a gate electrode formed of polysilicon according to a related art.

Additionally, according to embodiments of the present invention, the low resistance of the gate electrode can allow the gate electrode to have a small thickness, thereby allowing a step height between the semiconductor substrate 10 and the gate electrode to be reduced. This can allow an interlayer dielectric that may be subsequently formed on the semiconductor substrate 10 to be thin. Consequently, a contact connected the source and drain regions 90 can be formed more easily.

A method of manufacturing a semiconductor device according to an embodiment will now be described.

Referring to FIG. 6, a device isolation layer 20 can be formed in the semiconductor substrate 10 to define an active region. A gate dielectric layer 30a and a metal silicon layer 55a can be formed on the semiconductor substrate 10. A photoresist pattern 70 can be formed on the metal silicon layer 55a.

The device isolation layer 20 can be formed of any suitable material known in the art. In an embodiment, the device isolation layer 20 can be formed of an oxide. The device isolation layer 20 can be formed through any suitable process known in the art, for example, an STI process or a LOCOS process.

The gate dielectric layer 30a can be formed of any suitable material(s) known in the art. For example, the gate dielectric layer 30a can be formed of an oxide layer, a nitride layer, or a multilayered structure with an oxide layer and a nitride layer stack.

In an embodiment, the metal silicon layer 55a can be obtained by decomposing a Si-containing gas, and a gas containing W, Ti, Co, or any combination thereof using heat or plasma, and depositing it on the gate dielectric layer 30a in the deposition chamber. For example, the Si-containing gas can be SiH₄.

The metal silicon layer 55a can comprise a WSi layer, a TiSi layer, a CoSi layer, or any combination thereof.

After depositing the metal silicon layer 55a, a heat treatment process can be performed at a temperature of from about 500° C. to about 700° C. under a gas atmosphere containing N₂ and H₂. This heat treatment process can help stabilize the metal silicon layer 55a.

Referring to FIG. 7, portions of the metal silicon layer 55a and the gate dielectric layer 30a can be selectively removed using the photoresist pattern 70 as a mask, resulting in the formation of a gate electrode.

Thereafter, impurity ions can be implanted into the semiconductor substrate 10, using the gate electrode as a mask, to form LDD regions 80.

Referring to FIG. 8, sidewall spacers 60 can be formed on sides of the gate electrode. Then, the sidewall spacers 60 and the gate electrode can be used as a mask during an implantation process of impurity ions to form source and drain regions 90.

The sidewall spacers 60, the LDD regions 80, and source and drain regions 90 can each be formed through any suitable process known in the art.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device, comprising:
a gate dielectric on a semiconductor substrate; and
a gate electrode on the gate dielectric; wherein the gate electrode comprises an electrode seed layer on the gate dielectric and an electrode metal layer on the electrode seed layer.

2. The semiconductor device according to claim 1, further comprising:
sidewall spacers on sides of the gate electrode; and
source and drain regions in the semiconductor substrate at the sides of the gate electrode.

3. The semiconductor device according to claim 1, wherein the electrode seed layer comprises polysilicon.

4. The semiconductor device according to claim 3, wherein the electrode seed layer has a thickness of from about 10 Å to about 200 Å.

5. The semiconductor device according to claim 1, wherein the electrode metal layer comprises tungsten (W), titanium (Ti), cobalt (Co), or any combination thereof.

6. The semiconductor device according to claim 1, wherein the gate electrode further comprises a WSi layer, a TiSi layer, or a CoSi layer at a boundary between the electrode seed layer and the electrode metal layer.

7. A method of manufacturing a semiconductor device, comprising:
forming a gate dielectric on a semiconductor substrate; and
forming a gate electrode on the gate dielectric; wherein the gate electrode comprises an electrode seed layer on the gate dielectric and an electrode metal layer on the electrode seed layer.

8. The method according to claim 1, further comprising:
forming sidewall spacers on sides of the gate electrode; and
forming source and drain regions in the semiconductor substrate at the sides of the gate electrode.

9. The method according to claim 7, wherein forming the gate electrode comprises:
forming a seed layer on the gate dielectric layer;
forming a metal layer on the seed layer;
forming a photoresist pattern on the metal layer; and
selectively removing at least a portion of the metal layer, at least a portion of the seed layer, and at least a portion of the gate dielectric layer using the photoresist pattern as a mask.

10. The method according to claim 9, wherein forming the seed layer comprises thermally decomposing SiH₄ to form a polysilicon layer on the gate dielectric layer through a low pressure chemical vapor deposition (LPCVD) method; wherein the polysilicon layer has a thickness of from about 10 Å to about 200 Å.

11. The method according to claim 9, wherein forming the metal layer comprises:
decomposing a gas comprising W, Ti, Co, or any combination thereof using heat or plasma; and
depositing the decomposed gas on the seed layer to form the metal layer comprising W, Ti, Co, or any combination thereof.

12. The method according to claim 9, wherein forming the gate electrode further comprises heat-treating the seed layer and the metal layer to form a WSi layer, a TiSi layer, or a CoSi layer at a boundary between the seed layer and the metal layer, before forming the photoresist pattern.

13. A semiconductor device, comprising:
a gate dielectric on a semiconductor substrate; and
a gate electrode on the gate dielectric; wherein the gate electrode comprises an electrode metal silicon layer directly deposited on the gate dielectric.

14. The semiconductor device according to claim 13, further comprising:
sidewall spacers on sides of the gate electrode; and
source and drain regions in the semiconductor substrate at the sides of the gate electrode.

15. The semiconductor device according to claim 13, wherein the electrode metal silicon layer comprises WSi, TiSi, CoSi, or any combination thereof.

16. A method of manufacturing a semiconductor device, comprising:
forming a gate dielectric on a semiconductor substrate; and
forming a gate electrode on the gate dielectric; wherein the gate electrode comprises an electrode metal silicon layer deposited on the gate dielectric.

17. The method according to claim 16, further comprising:
forming sidewall spacers on sides of the gate electrode; and
forming source and drain regions in the semiconductor substrate at the sides of the gate electrode.

18. The method according to claim 16, wherein forming the gate electrode comprises:
depositing a metal silicon layer on the gate dielectric layer;
forming a photoresist pattern on the metal silicon layer; and
selectively removing at least a portion of the metal silicon layer and at least a portion of the gate dielectric layer using the photoresist pattern as a mask.

19. The method according to claim 18, wherein depositing the metal silicon layer comprises:
decomposing a Si-containing gas and a gas comprising W, Ti, Co, or any combination thereof using heat or plasma; and
depositing the metal silicon layer on the gate dielectric in a deposition chamber.

20. The method according to claim 16, wherein the electrode metal silicon layer comprises WSi, TiSi, CoSi, or any combination thereof.
